(19) United States
(12) Patent Application Publication
(10) Pub. No.: US 2025/0343190 A1
(43) Pub. Date: Nov. 6, 2025

(54) SEMICONDUCTOR PACKAGE AND METHOD OF FABRICATING THE SAME

(71) Applicant: Samsung Electronics Co., Ltd., Suwon-si (KR)

(72) Inventors: Un-Byoung KANG, Suwon-si (KR); Jiyoung PARK, Suwon-si (KR); Jeonggi JIN, Suwon-si (KR)

(73) Assignee: Samsung Electronics Co., Ltd., Suwon-si (KR)

(21) Appl. No.: 18/973,732

(22) Filed: Dec. 9, 2024

(30) Foreign Application Priority Data
May 3, 2024 (KR) 10-2024-0059303

(51) Int. Cl. H01L 23/00; H01L 23/31; H01L 25/00; H01L 25/07; H01L 25/11

(52) U.S. Cl. CPC H01L 24/13; H01L 23/3135; H01L 25/074; H01L 25/117; H01L 25/50; H01L 2224/13083; H01L 2224/13084; H01L 2225/06562; H01L 2225/1041

(57) ABSTRACT

Example embodiments are directed to a semiconductor package including a first structure having a second semiconductor chip on a first semiconductor chip and horizontally offset from the first semiconductor chip in a first direction, and a first insulating pattern covering side surfaces of the first semiconductor chip. A width of the first insulating pattern decreases in a direction from a lower surface of the first semiconductor chip toward an upper surface of the first semiconductor chip. The semiconductor package further comprises a first mold layer surrounding the first semiconductor chip, the second semiconductor chip, and the first insulating pattern, a first conductive post that vertically penetrates the first mold layer and coupled to the upper surface of the first semiconductor chip, and a second conductive post coupled to an upper surface of the second semiconductor chip and exposed through an upper surface of the first mold layer.

### CROSS-REFERENCE TO RELATED APPLICATIONS

This U.S. non-provisional patent application claims priority under 35 U.S.C. § 119 to Korean Patent Application No. 10-2024-0059303, filed on May 3, 2024, in the Korean Intellectual Property Office, the entire contents of which are hereby incorporated by reference.

### BACKGROUND

Example embodiments of the present disclosure relate to a semiconductor package and a method of fabricating the same.

With the recent advance in the electronics industry, the demand for high-performance, high-speed, and compact electronic components are increasing. To meet this demand, packaging technologies of mounting a plurality of semiconductor chips in a single package are being developed.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. With the recent development of the electronics industry, a semiconductor package technology is developing in various ways with the goal of miniaturization, weight reduction, and manufacturing cost reduction. Furthermore, as the utilization of this technology expands to different fields, including mass storage devices, several types of semiconductor packages are emerging.

As the integration density of semiconductor chips increases, their size gradually decreases. However, in the case where the size of the semiconductor chip is reduced, it is increasingly difficult to attach a high number of solder balls to the semiconductor chip and to handle and test the solder balls. In addition, it is necessary to change a board in accordance with a size of a semiconductor chip, which is difficult.

### SUMMARY

According to some example embodiments of the inventive concepts, a semiconductor package may include a first structure having a first semiconductor chip, a second semiconductor chip on the first semiconductor chip and horizontally offset from the first semiconductor chip in a first direction, and a first insulating pattern covering side surfaces of the first semiconductor chip. A width of the first insulating pattern decreases in a direction from a lower surface of the first semiconductor chip toward an upper surface of the first semiconductor chip. The semiconductor package further includes a first mold layer surrounding the first semiconductor chip, the second semiconductor chip, and the first insulating pattern, a first conductive post vertically penetrating the first mold layer and coupled to the upper surface of the first semiconductor chip, and a second conductive post coupled to an upper surface of the second semiconductor chip and exposed through an upper surface of the first mold layer.

According to some example embodiments of the inventive concepts, a semiconductor package may include a first chip stack including a stack of first semiconductor chips, each of the first semiconductor chips having a first chip pad on a top surface thereof, a first mold layer covering the first chip stack, a passivation layer covering an upper surface of the first mold layer, first conductive posts vertically penetrating the first mold layer and coupled to the first chip pads, and first seed patterns vertically penetrating the passivation layer and connected to the first conductive posts.

According to some example embodiments of the inventive concepts, a semiconductor package may include a first structure having a first semiconductor chip having a first chip pad provided on an upper surface thereof, a second semiconductor chip disposed on the first semiconductor chip and horizontally offset from the first semiconductor chip in a first direction, the second semiconductor chip having a second chip pad on an upper surface thereof, a first mold layer covering the first semiconductor chip and the second semiconductor chip, a first seed pattern on an upper surface of the first chip pad, a first conductive post vertically penetrating the first mold layer and in contact with the first seed pattern, and a second conductive post vertically penetrating the first mold layer and in contact with the second chip pad.

According to some example embodiments of the inventive concepts, a method of fabricating a semiconductor package may include attaching a first semiconductor chip to a carrier substrate, forming a first insulating pattern on a side surface of the first semiconductor chip, the first insulating pattern having an inclined surface connecting an upper surface of the carrier substrate to an upper surface of the first semiconductor chip, forming a first seed layer to cover the carrier substrate, the first insulating pattern, and the first semiconductor chip, forming a first conductive post on the first seed layer, the first conductive post being positioned on the first semiconductor chip, patterning the first seed layer using the first conductive post as a mask, attaching a second semiconductor chip to the first semiconductor chip to be horizontally spaced apart from the first conductive post, the second semiconductor chip having a second conductive post on a top surface thereof, forming a first mold layer on the carrier substrate to cover the first and second semiconductor chips, and forming a passivation layer to cover the first mold layer, the passivation layer defining openings for the first and second conductive posts.

### BRIEF DESCRIPTION OF THE DRAWINGS

The above and other aspects, features and other advantages of the example embodiments will be more clearly understood from the following detailed description, taken in conjunction with the accompanying drawings.

FIG. 1 is a sectional view illustrating a semiconductor package according to some example embodiments of the inventive concepts.

FIG. 2 is an enlarged sectional view illustrating a portion ‘A’ of FIG. 1.

FIGS. 3, 4, 5, 6, 7, and 8 are cross-sectional views illustrating a semiconductor package according to some example embodiments of the inventive concepts.

FIGS. 9, 10, 11, 12, 13, 14, 15, 16, 17, 18, 19, 20, 21, 22, 23, 24, 25, 26, 27, and 28 are cross-sectional views illustrating operations in a method of fabricating a semiconductor package according to some example embodiments of the inventive concepts.

### DETAILED DESCRIPTION

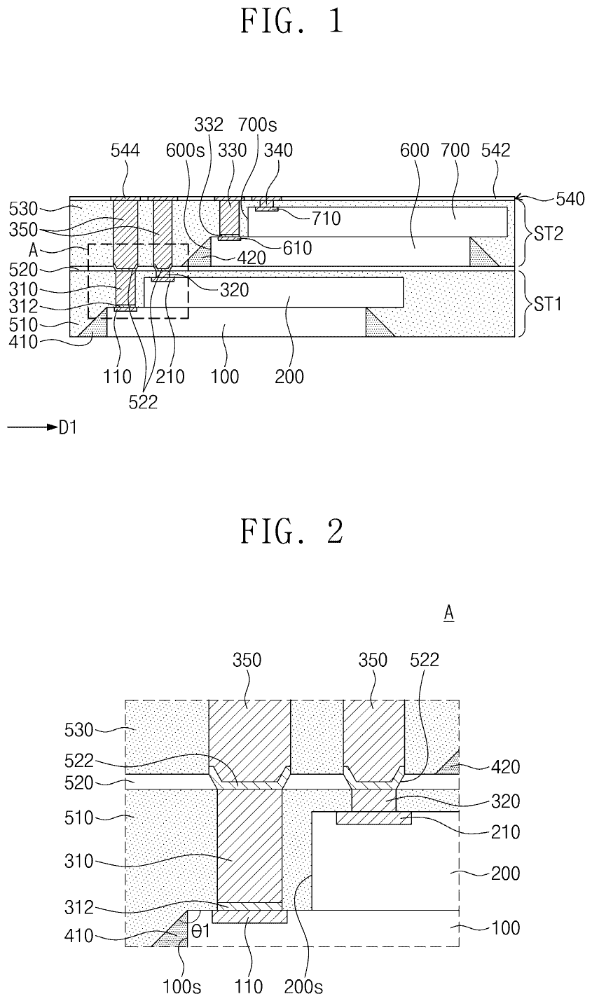

FIG. 1 is a cross-sectional view illustrating a semiconductor package, according to some example embodiments of the inventive concepts. FIG. 2 is an enlarged sectional view illustrating a portion ‘A’ of FIG. 1.

Referring to FIGS. 1 and 2, the semiconductor package may include a first structure ST1 and a second structure ST2 disposed on the first structure ST1.

The first structure ST1 may include a first chip stack. The first chip stack may include a first (or lower) semiconductor chip 100 and a second (or upper) semiconductor chip 200 stacked on the first semiconductor chip 100 in a vertical direction (with reference to the orientation in the figure). The first and second semiconductor chips 100 and 200 may be of the same kind or of different kinds. For example, the first and second semiconductor chips 100 and 200 may be memory chips (e.g., DRAM, SRAM, MRAM, or FLASH memory chips). Alternatively, the first semiconductor chip 100 may be a logic chip (e.g., a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.), and the second semiconductor chip 200 may be a memory chip. FIG. 1 illustrates the first chip stack having two semiconductor chips 100 and 200, but example embodiments are not limited thereto this example. The first chip stack may include 3 or more semiconductor chips stacked in various configurations. For instance, the first chip stack may further include at least one semiconductor chip, which is provided between the first and second semiconductor chips 100 and 200, or one or more semiconductor chip above and/or below the first and second semiconductor chips 100 and 200.

The first semiconductor chip 100 may have a front (or top or upper) surface and a rear (or bottom or lower) surface, which are opposite to each other. In other words, the first semiconductor chip 100 may be disposed in a face-up manner. The first semiconductor chip 100 may include first chip pads 110 provided on the top surface. The first chip pads 110 may be electrically connected to an integrated circuit included in the first semiconductor chip 100.

The second semiconductor chip 200 may be disposed on the first semiconductor chip 100 in a face-up manner. For example, the second semiconductor chip 200 may have a rear (or bottom or lower) surface, which faces the first semiconductor chip 100, and a front (or top or upper) surface, which is opposite to the rear surface. The second semiconductor chip 200 may include second chip pads 210 provided on the top surface of the second semiconductor chip 200. The second chip pads 210 may be electrically connected to an integrated circuit included in the second semiconductor chip 200.

Although FIG. 1 illustrates the first and second semiconductor chips 100 and 200, each including one chip pad 110 or 210, embodiments are not limited thereto and, each of the first and second semiconductor chips 100 and 200 may respectively include a plurality of chip pads 110 and 210.

The first and second semiconductor chips 100 and 200 may be disposed to form an offset stacking structure. For example, the second semiconductor chip 200 may be offset (e.g., laterally offset) from the first semiconductor chip 100 in a first direction D1 parallel to the top surface of the first semiconductor chip 100, and the first and second semiconductor chips 100 and 200 may form an upward inclined stepwise structure (i.e., a cascade structure). As illustrated, a portion of the second semiconductor chip 200 may laterally extend beyond or otherwise overhang the first semiconductor chip 100 in the first direction D1.

Since the first and second semiconductor chips 100 and 200 are stacked to form the stepwise structure, a portion of the top surface of the first semiconductor chip 100 (hereinafter, “an exposed surface”) may be exposed. Because of the offset stacking direction of the first and second semiconductor chips 100 and 200, the exposed surface of the first semiconductor chip 100 may be adjacent or near a side surface 200s of the second semiconductor chip 200 in an opposite direction of the first direction D1. In other words, the exposed surface of the first semiconductor chip 100 may be adjacent or near the side surface 200s of the second semiconductor chip 200 opposite the overhanging portion of the second semiconductor chip 200. The offset stacking direction may be defined as the direction in which an upper one of the stacked semiconductor chips (e.g., second semiconductor chip 200) is shifted or offset from an underlying semiconductor chip of the stack. In the example of FIG. 1, the offset stacking direction of the first and second semiconductor chips 100 and 200 may be the first direction D1. The top (or upper) surfaces of the first and second semiconductor chips 100 and 200 may be referred to as active surfaces. For example, the first chip pads 110 of the first semiconductor chip 100 may be provided on the exposed surface of the top surface of the first semiconductor chip 100, and the second chip pads 210 of the second semiconductor chip 200 may be provided on the top surface of the second semiconductor chip 200. In other words, the first chip pads 110 of the first semiconductor chip 100 may be spaced apart from the second semiconductor chip 200 in the opposite direction of the first direction D1.

Each of the first and second semiconductor chips 100 and 200 may include vertical connection terminals, which are used for vertical interconnection. The vertical connection terminals may include first conductive posts 310, which are connected to the first semiconductor chip 100, and second conductive posts 320, which are connected to the second semiconductor chip 200. As illustrated in FIG. 2, the first conductive posts 310 and the second conductive posts 320 may be located within (e.g., entirely within) the first structure ST1.

The first conductive posts 310 may be provided on the first semiconductor chip 100. The first conductive posts 310 may be disposed on the top surface of the first semiconductor chip 100. The first semiconductor chip 100 may be electrically connected to at least one of fourth conductive posts 340, as discussed below, using the first conductive posts 310. The first conductive posts 310 may be disposed on the first chip pads 110 of the first semiconductor chip 100. The first conductive posts 310 may be electrically connected to the top surfaces of the first chip pads 110. The first conductive posts 310 may be connected to a respective one of the first chip pads 110. Each of the first conductive posts 310 may be a pillar-shaped (or column shaped) pattern that extends vertically. A width of the first conductive posts 310 may be the same along the vertical length of the first conductive posts 310 or the first conductive posts 310 may have a tapering structure in which a width thereof may decrease in the direction of the first chip pad 110. Thus, each first conductive post 310 may be widest at an end thereof farthest away from the first chip pad 110 and narrowest at the end that is proximate to the first chip pad 110. The top surfaces of each of the first conductive posts 310 may be at a level higher than the top surface of the second semiconductor chip 200. The first conductive posts 310 may include copper or tungsten, or the like.

First seed patterns 312 may be interposed between the first conductive posts 310 and the first chip pads 110. The first seed patterns 312 may be coupled to the top surfaces of the first chip pads 110. The first conductive posts 310 may be coupled to the top surfaces of the first seed patterns 312. The first seed patterns 312 may have a width that is substantially equal to that of the first conductive posts 310. The first seed patterns 312 may have side surfaces that may be vertically aligned to side surfaces of the first conductive posts 310. In some example embodiments, the width of the first conductive post 310 is smaller than the width of the first chip pad 110, and a portion of the top surface of the first chip pad 110 may not be covered with the first seed pattern 312 and may thus be exposed. The first seed patterns 312 may be formed of or include at least one of metallic materials (e.g., gold).

The second conductive posts 320 may be provided on the second semiconductor chip 200. The second conductive posts 320 may be disposed on the top surface of the second semiconductor chip 200. The second semiconductor chip 200 may be electrically connected to at least one of fourth conductive posts 340, which will be described below, using the second conductive posts 320. The second conductive posts 320 may be disposed on the second chip pads 210 of the second semiconductor chip 200. The second conductive posts 320 may be coupled to the top surfaces of the second chip pads 210. The second conductive posts 320 may be connected to a respective one of the second chip pads 210. Each of the second conductive posts 320 may be a pillar-shaped (or column shaped) pattern that extends vertically or may be a bump-shaped pattern. The top surfaces of the second conductive posts 320 may be substantially at a same level as the top surface of the first conductive posts 310. In some example embodiments, the second conductive posts 320 may include solder bumps.

The first chip stack may further include a first insulating pattern 410. The first insulating pattern 410 may be disposed on a side surface 100s of the first semiconductor chip 100. The first insulating pattern 410 may cover the entire side surface 100s of the first semiconductor chip 100. The first insulating pattern 410 may surround the first semiconductor chip 100, when viewed in a plan view. The first insulating pattern 410 may have a triangular cross-section. In some example embodiments, the first insulating pattern 410 may have a triangle cross-section having one side in contact with the side surface 100s of the first semiconductor chip 100. The first insulating pattern 410 may be widest at or adjacent the bottom surface of the first semiconductor chip 100 and a width thereof may decrease (e.g., gradually) in the vertical direction and the first insulating pattern 410 may have the least width at or adjacent the top surface of the first semiconductor chip 100. The uppermost portion of the first insulating pattern 410 may be located at the same level as the top surface of the first semiconductor chip 100. The uppermost portion of the first insulating pattern 410 may be in contact with the top surface of the first semiconductor chip 100. The bottom surface of the first insulating pattern 410 may be located at the same level as the bottom surface of the first semiconductor chip 100. A bottom surface of the first insulating pattern 410 may be coplanar with the bottom surface of the first semiconductor chip 100. In other words, the first insulating pattern 410 may have a side surface in contact with the side surface 100s of the first semiconductor chip 100, the bottom surface coplanar with the bottom surface of the first semiconductor chip 100, and an inclined surface connecting the side surface to the bottom surface. An angle θ1 between the top surface of the first semiconductor chip 100 and the inclined surface of the first insulating pattern 410 may range from 90° to 175°. The first insulating pattern 410 may include an insulating material. As an example, the first insulating pattern 410 may include an under-filling material. The first insulating pattern 410 may include an epoxy resin.

The first structure ST1 may further include a first mold layer 510. The first mold layer 510 may encapsulate the first chip stack. In some example embodiments, the first mold layer 510 may encapsulate the first insulating pattern 410, the first semiconductor chip 100, and/or the second semiconductor chip 200. The first mold layer 510 may be provided on the first insulating pattern 410, the first semiconductor chip 100, and the second semiconductor chip 200 to cover them. For example, the first mold layer 510 may cover the inclined surface of the first insulating pattern 410, the top surface of the first semiconductor chip 100, and the top surface of the second semiconductor chip 200. The top surface of the first mold layer 510 may be spaced apart from the first and second semiconductor chips 100 and 200. The first mold layer 510 may not contact, and, as a result, expose, the bottom surface of the first semiconductor chip 100. The bottom surface of the first mold layer 510 and the bottom surface of the first insulating pattern 410 and the bottom surface of the first semiconductor chip 100 may be coplanar with each other. The first mold layer 510 may surround the first and second conductive posts 310 and 320. The top surfaces of the first and second conductive posts 310 and 320 may be exposed to the outside of the first mold layer 510 at or near the top surface of the first mold layer 510. The top surfaces of the first and second conductive posts 310 and 320 may be coplanar with the top surface of the first mold layer 510. The first and second conductive posts 310 and 320 may vertically penetrate the first mold layer 510 and may be coupled to the first seed patterns 312 or the second chip pads 210, respectively.

A passivation layer 520 may be disposed on the first structure ST1. The passivation layer 520 may cover the top (or upper) surface of the first mold layer 510. The passivation layer 520 may have openings exposing the top surfaces of the first and second conductive posts 310 and 320. The passivation layer 520 may include an insulating material. For example, the passivation layer 520 may include an insulating polymer or a photoimageable polymer (PID). The photoimageable polymers may include at least one of photoimageable polyimide (PI), polybenzoxazole (PBO), phenol-based polymers, or benzocyclobutene-based polymers.

Second seed patterns 522 may be provided on the passivation layer 520. The second seed patterns 522 may be disposed in the openings of the passivation layer 520. For example, the second seed patterns 522 may be respectively disposed in the openings of the passivation layer 520. The second seed pattern 522 may conformally cover an inner side surface and a bottom surface of the opening of the passivation layer 520. On the bottom surfaces of the openings, the second seed patterns 522 may be in contact with the top surfaces of the first conductive posts 310 or the top surfaces of the second conductive posts 320. The second seed patterns 522 may be coupled to the top surface of the first conductive posts 310 or the top surface of the second conductive posts 320. The uppermost portion of the second seed patterns 522 may be at a level vertically higher than the top surface of the passivation layer 520. However, in some other example embodiments, the uppermost portion of the second seed patterns 522 may be located vertically at a same level as the top surface of the passivation layer 520. In some other example embodiment, at least a portion of the second seed patterns 522 may be formed or, otherwise, extend on the top surface of the passivation layer 520. The second seed patterns 522 may include a metallic material (e.g., gold).

The second structure ST2 may be disposed on the passivation layer 520. The second structure ST2 may include a second chip stack. The second chip stack may be spaced apart (e.g., laterally offset) from the second seed patterns 522 in the first direction D1. The second chip stack may include or have a third (or lower) semiconductor chip 600 and a fourth (or upper) semiconductor chip 700, which are stacked in a vertical direction (with reference to the orientation in the figure). The third and fourth semiconductor chips 600 and 700 may be semiconductor chips of the same kind or of different kinds. For example, the third and fourth semiconductor chips 600 and 700 may be memory chips (e.g., DRAM, SRAM, MRAM, or FLASH memory chips). Alternatively, the third semiconductor chip 600 may be a logic chip (e.g., a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.), and the fourth semiconductor chip 700 may be a memory chip. FIG. 1 illustrates the second chip stack having two semiconductor chips 600 and 700, but example embodiments are not limited thereto. The second chip stack may include 3 or more semiconductor chips stacked in various configurations. For instance, the second chip stack may further include one or more semiconductor chips provided between the third and fourth semiconductor chips 600 and 700, or one or more semiconductor chip above and/or below the third and fourth semiconductor chips 600 and 700.

The third semiconductor chip 600 may include a front (or top) surface and a rear (or bottom) surface, which are opposite to each other. In other words, the third semiconductor chip 600 may be disposed on the passivation layer 520 in a face-up manner. The third semiconductor chip 600 may include third chip pads 610 provided on the top surface. The third chip pads 610 may be electrically connected to an integrated circuit of the third semiconductor chip 600.

The fourth semiconductor chip 700 may be disposed on the third semiconductor chip 600 in a face-up manner. For example, the fourth semiconductor chip 700 may have a rear (or bottom) surface, which faces the third semiconductor chip 600, and a front (or top) surface, which is opposite to the rear surface. The fourth semiconductor chip 700 may include fourth chip pads 710 provided on the top surface of the fourth semiconductor chip 700. The fourth chip pads 710 may be electrically connected to an integrated circuit of the fourth semiconductor chip 700.

Although FIG. 1 illustrates the third and fourth semiconductor chips 600 and 700, each of which has one chip pad 610 or 710, example embodiments of the disclosure are not limited thereto. In some other example embodiments, each of the third and fourth semiconductor chips 600 and 700 may include a plurality of chip pads 610 or 710.

The third and fourth semiconductor chips 600 and 700 may be disposed to form an offset stacking structure. For example, the fourth semiconductor chip 700 may be laterally offset from the third semiconductor chip 600 in the first direction D1 parallel to the top surface of the third semiconductor chip 600, and the third and fourth semiconductor chips 600 and 700 may form an upward inclined stepwise structure (i.e., a cascade structure). As illustrated, a portion of the fourth semiconductor chip 700 may laterally extend beyond or overhang the third semiconductor chip 600 in the first direction D1.

Since the third and fourth semiconductor chips 600 and 700 are stacked to form the stepwise structure, a portion of the top surface of the third semiconductor chip 600 (hereinafter, “an exposed surface”) may be exposed. Because of the offset stacking direction of the third and fourth semiconductor chips 600 and 700, the exposed surface of the third semiconductor chip 600 may be adjacent or near a side surface 700s of the fourth semiconductor chip 700 in the opposite direction of the first direction D1. In other words, the exposed surface of the third semiconductor chip 600 may be adjacent or near the side surface 700s of the fourth semiconductor chip 700 opposite the overhanging portion of the fourth semiconductor chip 700. The offset stacking direction may be defined as the direction in which an upper one of the stacked semiconductor chips (e.g., fourth semiconductor chip 700) is shifted or offset from an underlying semiconductor chip of the stack. In the example of FIG. 1, the offset stacking direction of the third and fourth semiconductor chips 600 and 700 may be the first direction D1. The top (or upper) surfaces of the third and fourth semiconductor chips 600 and 700 may be referred to as active surfaces. For example, the third chip pads 610 of the third semiconductor chip 600 may be provided on the exposed surface of the top surface of the third semiconductor chip 600, and the fourth chip pads 710 of the fourth semiconductor chip 700 may be provided on the top surface of the fourth semiconductor chip 700. In other words, the third chip pads 610 of the third semiconductor chip 600 may be spaced apart from the fourth semiconductor chip 700 in the opposite direction of the first direction D1. FIG. 1 illustrates an example, in which the offset stacking direction of the first and second semiconductor chips 100 and 200 and the offset stacking direction of the third and fourth semiconductor chips 600 and 700 are the same direction (e.g., the first direction D1), but example embodiments are not limited thereto. In some example embodiments, the offset stacking direction of the first and second semiconductor chips 100 and 200 may be different (e.g., opposite) from the offset stacking direction of the third and fourth semiconductor chips 600 and 700.

Each of the third and fourth semiconductor chips 600 and 700 may include vertical connection terminals, which are used for vertical interconnection. The vertical connection terminals may include third conductive posts 330 connected to the third semiconductor chip 600 and the fourth conductive posts 340 connected to the fourth semiconductor chip 700.

The third conductive posts 330 may be provided on the third semiconductor chip 600. The third conductive posts 330 may be disposed on the top surface of the third semiconductor chip 600. The third semiconductor chip 600 may be electrically connected to a pad layer 540 using the third conductive posts 330. The third conductive posts 330 may be disposed on the third chip pads 610 of the third semiconductor chip 600. The third conductive posts 330 may be electrically connected to the top surfaces of the third chip pads 610. A plurality of third conductive posts 330 may be connected to respective one of the third chip pads 610. Each of the third conductive posts 330 may be pillar-shaped (or column shaped) that extends vertically. A width of the third conductive posts 330 may be the same along the vertical extent thereof or third conductive posts 330 may have a tapering shape in which a width thereof vertically decreases in the direction of the third chip pad 610. A top surface of the third conductive post 330 may be at a higher level than the top surface of the fourth semiconductor chip 700. In some example embodiments, the third conductive posts 330 may include copper or tungsten.

Third seed patterns 332 may be interposed between the third conductive posts 330 and the third chip pads 610. The third seed patterns 332 may be coupled to the top surfaces of the third chip pads 610. The third conductive posts 330 may be coupled to the top surface of the third seed patterns 332. A width of the third seed patterns 332 may be about the same as a width of the third conductive posts 330. A side surface of the third seed pattern 332 may be vertically aligned with the side surface of the third conductive post 330. In some example embodiments, a width of the third conductive posts 330 may be smaller than the width of the third chip pads 610, and a portion of the top surface of the third chip pad 610 may not be covered with the third seed pattern 332 and may thus be exposed. A vertical thickness of the third seed patterns 332 may be substantially equal or similar to a vertical thickness of the second seed patterns 522. The third seed patterns 332 may include the same material as the second seed patterns 522. In some example embodiments, the third seed patterns 332 may be or include at least one of metallic materials (e.g., gold).

The fourth conductive posts 340 may be provided on the fourth semiconductor chip 700. The fourth conductive posts 340 may be disposed on the top surface of the fourth semiconductor chip 700. The fourth semiconductor chip 700 may be electrically connected to the pad layer 540 using the fourth conductive posts 340. The fourth conductive posts 340 may be disposed on the fourth chip pads 710 of the fourth semiconductor chip 700. The fourth conductive posts 340 may be coupled to the top surfaces of the fourth chip pads 710. A plurality of fourth conductive posts 340 may be connected to a respective one of the fourth chip pads 710. Each of the fourth conductive posts 340 may be a pillar-shaped (or column shaped) pattern that extends vertically or may be a bump-shaped pattern. The top surface of the fourth conductive posts 340 may be substantially at a same level as the top surface of the third conductive posts 330. In some example embodiments, the fourth conductive posts 340 may include solder bumps.

The second chip stack may further include a second insulating pattern 420. The second insulating pattern 420 may contact the side surface 600s of the third semiconductor chip 600. In some example embodiments, the second insulating pattern 420 may entirely cover the side surface of the third semiconductor chip 600. The second insulating pattern 420 may surround the third semiconductor chip 600, when viewed in a plan view. The second insulating pattern 420 may have a triangular cross-section. In some example embodiments, the second insulating pattern 420 may have a triangle shape having one side is in contact with the side surface of the third semiconductor chip 600. The side of the second insulating pattern 420 opposite the side contacting the side surface of the third semiconductor chip 600 may be inclined from the bottom surface of the third semiconductor chip 600 toward the top surface of the third semiconductor chip 600. The uppermost portion of the second insulating pattern 420 may be located at the same level as the top surface of the third semiconductor chip 600. The uppermost portion of the second insulating pattern 420 may be in contact with the top surface of the third semiconductor chip 600. A bottom surface of the second insulating pattern 420 may be located at a same level as the bottom surface of the third semiconductor chip 600. The bottom surface of the third semiconductor chip 600 and the bottom surface of the second insulating pattern 420 may be in contact with the top surface of the passivation layer 520. The bottom surface of the second insulating pattern 420 may be coplanar with the bottom surface of the third semiconductor chip 600. In other words, the second insulating pattern 420 may have a side surface in contact with the side surface 600s of the third semiconductor chip 600, a bottom surface coplanar with the bottom surface of the third semiconductor chip 600, and an inclined surface connecting the side surface to the bottom surface. An angle between the top surface of the third semiconductor chip 600 and the inclined surface of the second insulating pattern 420 may range from 90° to 175°. The second insulating pattern 420 may include an insulating material. As an example, the second insulating pattern 420 may include an under-filling material, such as, an epoxy resin, for instance.

The second structure ST2 may further include a second mold layer 530. In some example embodiments, the second mold layer 530 may be formed on the second insulating pattern 420, the third semiconductor chip 600, and the fourth semiconductor chip 700 and may cover the second insulating pattern 420, the third semiconductor chip 600, and the fourth semiconductor chip 700. A top surface of the second mold layer 530 may be spaced apart from the third and fourth semiconductor chips 600 and 700. The second mold layer 530 may not be formed on the bottom surface of the third semiconductor chip 600. The bottom surface of the second mold layer 530 may be coplanar with the bottom surface of the second insulating pattern 420 and the bottom surface of the third semiconductor chip 600. The second mold layer 530 may surround or, otherwise, enclose the third and fourth conductive posts 330 and 340. The top surfaces of the third and fourth conductive posts 330 and 340 may be exposed through the top surface of the second mold layer 530. The top surfaces of the third and fourth conductive posts 330 and 340 may be coplanar with the top surface of the second mold layer 530. The third and fourth conductive posts 330 and 340 may vertically penetrate the second mold layer 530 and may be coupled to the third seed patterns 332 or the fourth chip pads 710.

The second structure ST2 may further include fifth conductive posts 350, which are used for vertical interconnection of the first and second semiconductor chips 100 and 200. The fifth conductive posts 350 may vertically penetrate the second mold layer 530 and may be coupled to the second seed patterns 522. Top surfaces of the fifth conductive posts 350 may be exposed through the top surface of the second mold layer 530. The top surfaces of the fifth conductive posts 350 may be coplanar with the top surface of the second mold layer 530.

A pad layer 540 may be disposed on the second structure ST2. The pad layer 540 may cover the top surface of the second mold layer 530. The pad layer 540 may be vertically spaced apart from the second chip stack. For example, a bottom surface of the pad layer 540 and the top surface of the fourth semiconductor chip 700 may be spaced apart from each other. The pad layer 540 may connect the first to fourth semiconductor chips 100, 200, 600, and 700 to an external structure or circuits. The pad layer 540 may include a pad insulating layer 542 and pads 544 in the pad insulating layer 542.

The pad insulating layer 542 may include at least one of inorganic insulating materials (e.g., silicon oxide or silicon nitride). Alternatively, the pad insulating layer 542 may include a polymer material. The pad insulating layer 542 may include an insulating polymer or a photoimageable polymer (PID). For example, the photoimageable polymers may include at least one of photoimageable polyimide (PI), polybenzoxazole (PBO), phenol-based polymers, or benzocyclobutene-based polymers.

The pads 544 may be provided in the pad insulating layer 542. The pads 544 may be exposed through the pad insulating layer 542 at or near top (or upper) and bottom (or lower) surfaces of the pad insulating layer 542. When viewed in a plan view, the pads 544 may be placed at positions corresponding to the third to fifth conductive posts 330, 340, and 350. The pads 544 may be coupled (e.g., electrically) with the third to fifth conductive posts 330, 340, and 350. For example, third to fifth conductive posts 330, 340, and 350 may vertically penetrate the second mold layer 530 and may be coupled to bottom surfaces of the pads 544. The first semiconductor chip 100 may be electrically connected to the pads 544 through the first conductive posts 310, the second seed patterns 522, and the fifth conductive posts 350. The second semiconductor chip 200 may be electrically connected to the pads 544 through the second conductive posts 320, the second seed patterns 522, and the fifth conductive posts 350. The third semiconductor chip 600 may be electrically connected to the pads 544 through the third conductive posts 330. The fourth semiconductor chip 700 may be electrically connected to the pads 544 through the fourth conductive posts 340. The pads 544 may include a conductive material. For example, the pads 544 may include copper.

According to some example embodiments of the inventive concepts, the second structure ST2 having the second chip stack may be provided on the first structure ST1 having the first chip stack. Here, the first, second and fifth conductive posts 310, 320, and 350 may be relatively thicker and may vertically interconnect the first and second semiconductor chips 100 and 200 of the first chip stack. Thus, the first, second and fifth conductive posts 310, 320, and 350, which are provided between the first and second semiconductor chips 100 and 200 and the pad layer 540, may robustly or reliably support the first and second semiconductor chips 100 and 200 and the pad layer 540. In addition, the first, second and fifth conductive posts 310, 320, and 350 may provide a low electric resistance path between the first and second semiconductor chips 100 and 200 and the pad layer 540. Accordingly, the semiconductor package may have improved structural stability and electric characteristics.

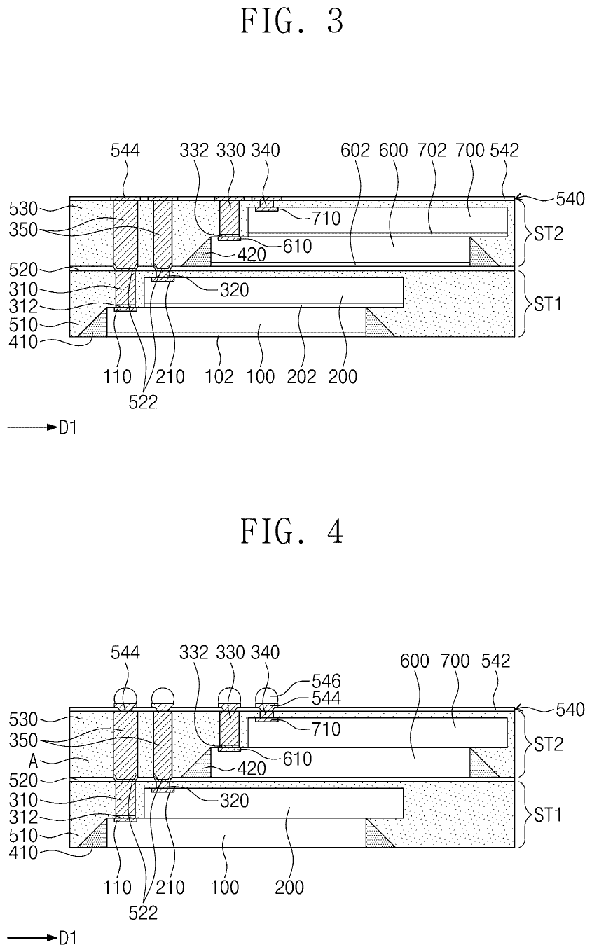

FIG. 3 is a sectional view illustrating a semiconductor package according to some example embodiments of the inventive concepts. The semiconductor package of FIG. 3 may be the same in some respects to the semiconductor package of FIG. 1, and therefore may be best understood with reference thereto where like numerals indicate like elements not described again in detail.

Referring to FIG. 3, the first and second structures ST1 and ST2 may include first to fourth adhesive layers 102, 202, 602, and 702, which are provided below the semiconductor chips 100, 200, 600, and 700, respectively. At least one of the first to fourth adhesive layers 102, 202, 602, and 702 may include a die attach film (DAF).

The first adhesive layer 102 may be formed on the bottom surface of the first semiconductor chip 100. The first adhesive layer 102 may cover the bottom surface of the first semiconductor chip 100. The first insulating pattern 410 may enclose or surround the first semiconductor chip 100 and the first adhesive layer 102. The bottom surface of the first insulating pattern 410 may be coplanar with the bottom surface of the first adhesive layer 102.

The second adhesive layer 202 may be formed on the bottom surface of the second semiconductor chip 200. The second adhesive layer 202 may cover the bottom surface of the second semiconductor chip 200. The second semiconductor chip 200 may be attached to the top surface of the first semiconductor chip 100 using the second adhesive layer 202.

The third adhesive layer 602 may be formed on the bottom surface of the third semiconductor chip 600. The third adhesive layer 602 may cover the bottom surface of the third semiconductor chip 600. The third semiconductor chip 600 may be attached to the top surface of the passivation layer 520 using the third adhesive layer 602. The second insulating pattern 420 may enclose or surround the third semiconductor chip 600 and the third adhesive layer 602. The bottom surface of the second insulating pattern 420 may be coplanar with the bottom surface of the third adhesive layer 602.

The fourth adhesive layer 702 may be formed on the bottom surface of the fourth semiconductor chip 700. The fourth adhesive layer 702 may cover the bottom surface of the fourth semiconductor chip 700. The fourth semiconductor chip 700 may be attached to the top surface of the third semiconductor chip 600 using the fourth adhesive layer 702.

FIG. 4 is a sectional view illustrating a semiconductor package according to some example embodiments of the inventive concepts. The semiconductor package of FIG. 4 may be the same in some respects to the semiconductor package of FIG. 1, and therefore may be best understood with reference thereto where like numerals indicate like elements not described again in detail.

Referring to FIG. 4, the pad layer 540 may be disposed on the second structure ST2 and may be vertically spaced apart from the second structure ST2. The pad layer 540 may connect the first to fourth semiconductor chips 100, 200, 600, and 700 to an external structure or circuit. The pad layer 540 may include the pad insulating layer 542 and the pads 544 in the pad insulating layer 542. In some example embodiments, a plurality of outer coupling terminals 546 may be provided on respective one of the pads 544.

The pads 544 may have a damascene structure. For example, each of the pads 544 may have a head portion and a tail portion, which are connected to form a single, unitary structure. The head portion may be a wire or pad portion, which is used to extend a wire in the pad layer 540 in a horizontal direction. The tail portion may be a via portion, which is used to connect wires in the pad layer 540 to each other in a vertical direction. The pads 544 may have a ‘T’-shaped cross-section. The head portion of the pad 544 may be formed on a top (or upper) surface of the pad insulating layer 542, and the tail portion of the pad 544 may extend from a bottom surface of the head portion into the pad insulating layer 542. A portion of the head portion of the pad 544 may correspond to a pad of the pad layer 540. For example, a portion of the head portion of the pad 544 may be formed on the top surface of the pad insulating layer 542. That is, the pads 544 may protrude upward and outward relative to the top surface of the pad insulating layer 542. The third to fifth conductive posts 330, 340, and 350 may be coupled to bottom surfaces of the tail portions of the pads 544.

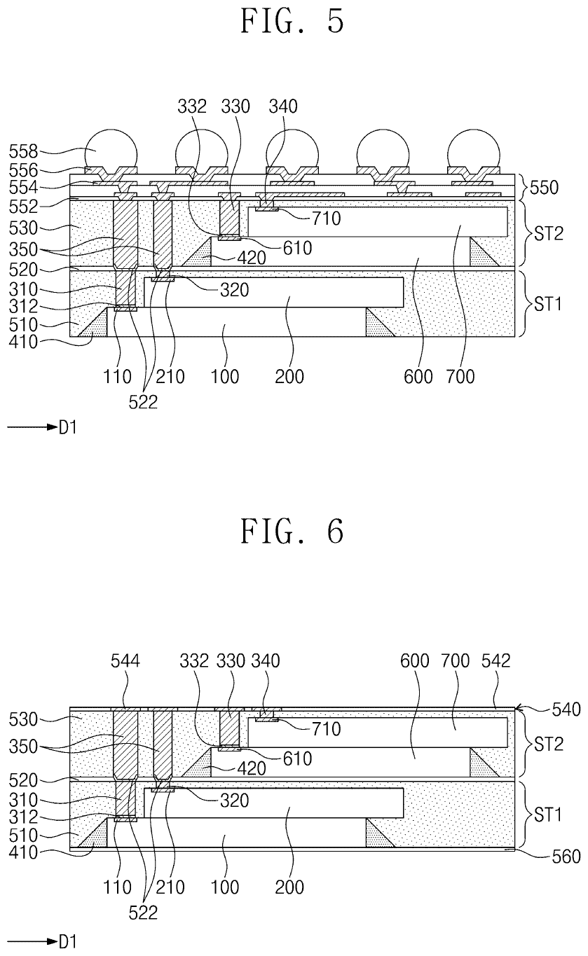

FIG. 5 is a sectional view illustrating a semiconductor package according to some example embodiments of the inventive concepts. The semiconductor package of FIG. 5 may be the same in some respects to the semiconductor package of FIG. 1, and therefore may be best understood with reference thereto where like numerals indicate like elements not described again in detail.

Referring to FIG. 5, the semiconductor package may include a package substrate 550, instead of the pad layer 540.

The package substrate 550 may be referred to as a redistribution substrate. For example, the package substrate 550 may include two or more substrate interconnection layers which are sequentially stacked. The substrate interconnection layer, also referred to as simply as an interconnection layer, is formed by patterning a single insulating layer and a single conductive layer. In some example embodiments, conductive patterns in each substrate interconnection layer may be horizontally-extended interconnection patterns that are not vertically overlapped with each other. Each of the substrate interconnection layers may include substrate insulating patterns 552 and substrate interconnection patterns 554 in the substrate insulating patterns 552. The substrate interconnection patterns 554 of one substrate interconnection layer may be electrically connected to the substrate interconnection patterns 554 of another substrate interconnection layer adjacent thereto.

The substrate insulating patterns 552 may be formed of or include at least one of inorganic insulating materials (e.g., silicon oxide or silicon nitride). Alternatively, the substrate insulating patterns 552 may be formed of or include at least one of polymer materials. The substrate insulating patterns 552 may include an insulating polymer or a photoimageable polymer (PID). For example, the photoimageable polymers may include at least one of photoimageable polyimide (PI), polybenzoxazole (PBO), phenol-based polymers, or benzocyclobutene-based polymers.

The substrate interconnection patterns 554 may be provided in the substrate insulating patterns 552. The substrate interconnection patterns 554 may have a damascene structure. For example, each of the substrate interconnection patterns 554 may have a head portion and a tail portion, which are connected to form a single, unitary structure. The head portion may be a wire or pad portion, which is used to extend a wire in the package substrate 550 in a horizontal direction. The tail portion may be a via portion, which is used to connect wires in the package substrate 550 to each other in a vertical direction. The substrate interconnection patterns 554 may have a ‘T’-shaped cross-section. In each of the substrate interconnection layers, the head portion of the substrate interconnection pattern 554 may be disposed or formed on a top surface of the substrate insulating pattern 552. The tail portion of the substrate interconnection pattern 554 in each of the substrate interconnection layers may extend from a bottom surface of the head portion to penetrate the substrate insulating pattern 552 of another substrate interconnection layer thereunder and may be coupled to the head portion of another substrate interconnection pattern 554. The substrate interconnection patterns 554 may include a conductive material. For example, the substrate interconnection patterns 554 may be formed of or include copper (Cu). The substrate interconnection patterns 554 may be used for redistribution of the semiconductor chips 100, 200, 600, and 700 in the semiconductor package.

The tail portions of the substrate interconnection patterns 554 of the lowermost one of the substrate interconnection layers may penetrate the substrate insulating pattern 552 and may be coupled to the third to fifth conductive posts 330, 340, and 350. Alternatively, pads, which are coupled with the third to fifth conductive posts 330, 340, and 350, may be additionally provided on the lowermost one of the substrate interconnection layers, and the lowermost ones of the substrate interconnection patterns 554 may penetrate the substrate insulating pattern 552 and may be coupled to the pads.

The semiconductor package may have a fan-out structure due to the package substrate 550. The substrate interconnection patterns 554 may be connected to outer pads 556 disposed on a top surface of the package substrate 550. A plurality of outer coupling terminals 558 may be disposed on a respective one of the outer pads 556. The outer pads 556 may penetrate the uppermost substrate insulating pattern 552 and may be coupled to the substrate interconnection patterns 554. In some example embodiments, a protection layer may be disposed on the top surface of the package substrate 550. The protection layer may cover the substrate insulating pattern 552 and the substrate interconnection patterns 554 and expose the outer pads 556.

FIG. 6 is a sectional view illustrating a semiconductor package according to some example embodiments of the inventive concepts. The semiconductor package of FIG. 6 may be the same in some respects to the semiconductor package of FIG. 1, and therefore may be best understood with reference thereto where like numerals indicate like elements not described again in detail.

Referring to FIG. 6, the semiconductor package may further include a protection layer 560.

The protection layer 560 may be formed on a bottom surface of the first structure ST1. The protection layer 560 may cover the bottom surface of the first mold layer 510, the bottom surface of the first insulating pattern 410, and the bottom surface of the first semiconductor chip 100. The protection layer 560 may protect the first structure ST1 (for example, the first semiconductor chip 100) from an external impact. The protection layer 560 may include an insulating polymer.

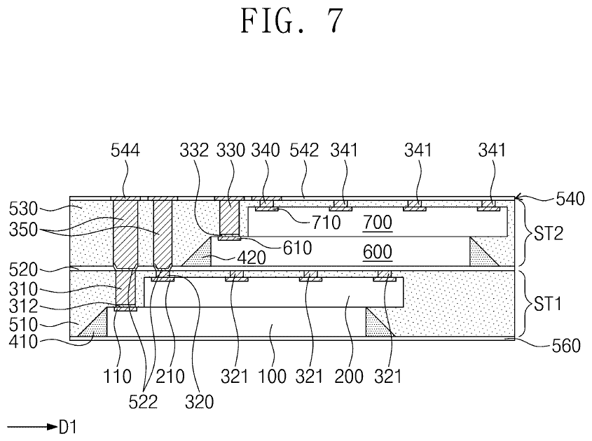

FIG. 7 is a sectional view illustrating a semiconductor package according to some example embodiments of the inventive concepts. The semiconductor package of FIG. 7 may be the same in some respects to the semiconductor package of FIGS. 1 and 6, and therefore may be best understood with reference thereto where like numerals indicate like elements not described again in detail.

Referring to FIG. 7, the second semiconductor chip 200 may further include first dummy bumps 321. The first dummy bumps 321 may be disposed on the top surface of the second semiconductor chip 200. The first dummy bumps 321 may be in contact with the top surface of the second semiconductor chip 200. The first dummy bumps 321 may be spaced apart from the second chip pads 210. The first dummy bumps 321 may be electrically disconnected or, otherwise, isolated, from the integrated circuit of the second semiconductor chip 200. A height of the first dummy bumps 321 may be substantially equal to a height of the second conductive posts 320. The first dummy bumps 321 may be in contact with the bottom surface of the passivation layer 520. Thus, the second semiconductor chip 200 and the first structure ST1 may be supported by the first dummy bumps 321 below the bottom surface of the passivation layer 520. As a result, the structural stability of the semiconductor package is improved. The first dummy bumps 321 may include solder bumps.

The fourth semiconductor chip 700 may further include second dummy bumps 341. The second dummy bumps 341 may be disposed on the top surface of the fourth semiconductor chip 700. The second dummy bumps 341 may be in contact with the top surface of the fourth semiconductor chip 700. The second dummy bumps 341 may be spaced apart from the fourth chip pads 710. The second dummy bumps 341 may be electrically disconnected or, otherwise, isolated, from the integrated circuit of the fourth semiconductor chip 700. A height of the second dummy bumps 341 may be substantially equal to a height of the fourth conductive posts 340. The second dummy bumps 341 may be in contact with the bottom surface of the pad layer 540. Thus, the fourth semiconductor chip 700 and the second structure ST2 may be supported by the second dummy bumps 341 below the bottom surface of the pad layer 540. As a result, the structural stability of the semiconductor package is improved. The second dummy bumps 341 may include solder bumps.

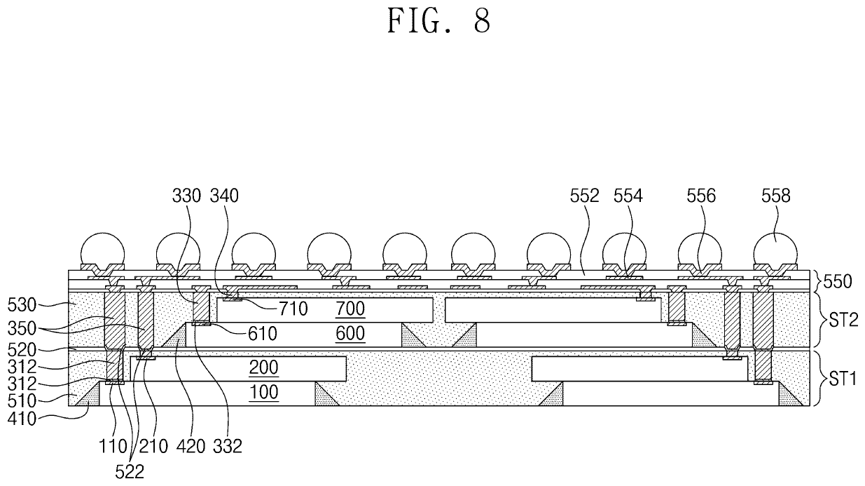

FIG. 8 is a sectional view illustrating a semiconductor package according to some example embodiments of the inventive concepts. The semiconductor package of FIG. 8 may be the same in some respects to the semiconductor package of FIGS. 1 and 5, and therefore may be best understood with reference thereto where like numerals indicate like elements not described again in detail.

Referring to FIG. 8, the first structure ST1 may include a plurality of first chip stacks. FIG. 8 illustrates an example including a pair of the first chip stacks, but example embodiments of the inventive concepts are not limited thereto. For example, the first structure ST1 may include three or more first chip stacks.

The first chip stacks may have respective offset stacking directions. The offset stacking directions of the first chip stacks may vary depending on the positions of the second seed patterns 522 of the passivation layer 520 and the positions of the first and second chip pads 110 and 210 of the first chip stack. For example, as shown in FIG. 8, the offset stacking direction of one of the first chip stack in the pair of first chip stacks may be the first direction D1. The offset stacking direction of the other of the first chip stack in the pair of first chip stacks may be opposite to the first direction D1. However, the offset stacking direction of the individual first chip stacks of the pair of first chip stacks is not limited to the example embodiments shown in FIG. 8, and may be varied as required by application and design.

The second structure ST2 may include a plurality of second chip stacks. FIG. 8 illustrates an example including a pair of the second chip stacks, but example embodiments of the inventive concepts are not limited thereto. For example, the second structure ST2 may include three or more second chip stacks.

The second chip stacks may have respective offset stacking directions. The offset stacking directions of the second chip stacks may vary depending on the positions of the pads 544 of the pad layer 540 and the positions of the third and fourth chip pads 610 and 710 of the second chip stack. For example, as shown in FIG. 8, the offset stacking direction of one of the second chip stack in the pair of the second chip stacks may be the first direction D1. The offset stacking direction of the other of the second chip stack in the pair of second chip stacks may be opposite to first direction D1. However, the offset stacking direction of the individual second chip stacks of the pair of second chip stacks is not limited to the example embodiments shown in FIG. 8, and may be varied as required by application and design.

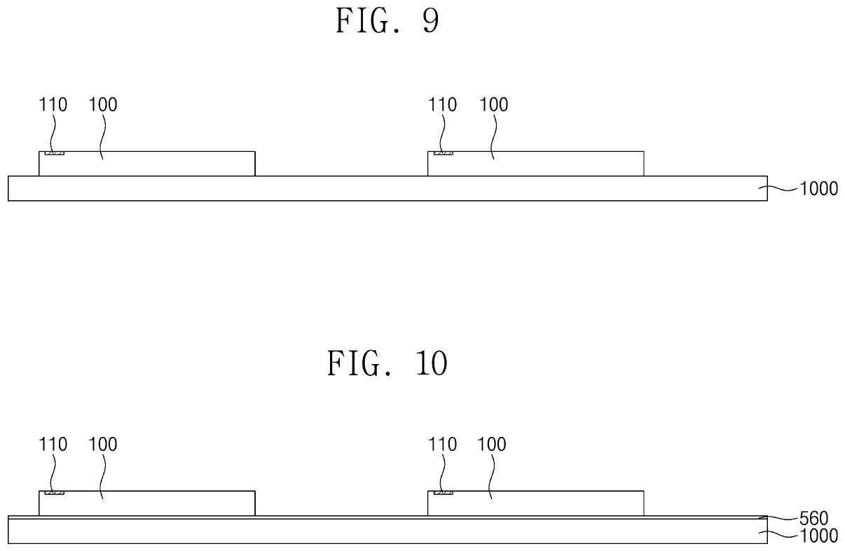

FIGS. 9 to 28 are sectional views illustrating operations in a method of fabricating a semiconductor package according to some example embodiments of the inventive concepts.

Referring to FIG. 9, a carrier substrate 1000 may be provided. The carrier substrate 1000 may be an insulating substrate including glass or polymer, or a conductive substrate including a metallic material. In some example embodiments, an adhesive member may be formed on a top surface of the carrier substrate 1000. For sake of clarity of illustration, the adhesive member is not illustrated in FIG. 9. As an example, the adhesive member may include an adhesive tape.

The first semiconductor chips 100 may be attached to the carrier substrate 1000 using the adhesive member. The first semiconductor chips 100 may be disposed in a face-up manner. In other words, the rear surface (also referred to as an inactive surface) of the first semiconductor chips 100 may face the carrier substrate 1000, and the first chip pads 110 of the first semiconductor chips 100 may be opposite to the carrier substrate 1000.

Referring briefly to FIG. 10, in some example embodiments, the protection layer 560 may be formed on or attached to the carrier substrate 1000, before the attaching of the first semiconductor chips 100 to the carrier substrate 1000. The protection layer 560 may cover an entirety of the top surface of the carrier substrate 1000. Next, the first semiconductor chips 100 may be attached to or disposed on a top surface of the protection layer 560. For the sake of explanation, the method discussed herein is directed to fabricating the semiconductor package described with reference to FIG. 6.

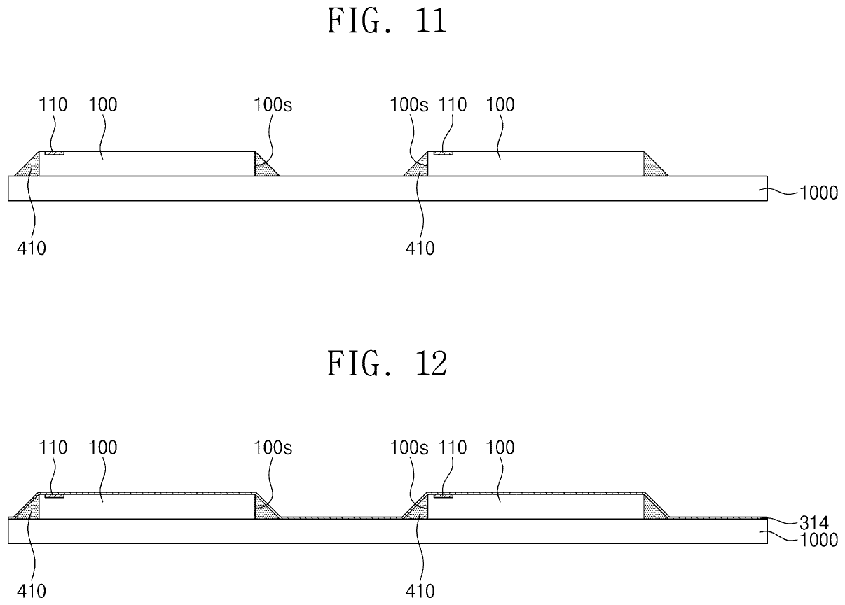

Returning back to FIG. 9, and continuing with reference to FIG. 11, the first insulating patterns 410 may be formed on the carrier substrate 1000. For example, the first insulating patterns 410 may be formed by depositing an insulating material into a space between the top surface of the carrier substrate 1000 and the side surfaces of the first semiconductor chips 100. The first insulating patterns 410 may be formed on the side surfaces 100s of the first semiconductor chips 100. The first insulating patterns 410 may cover the side surfaces 100s of the first semiconductor chips 100. The first insulating patterns 410 may surround the first semiconductor chips 100, when viewed in a plan view. The first insulating patterns 410 may fill or occupy a space on the top surface of the carrier substrate 1000 and between the side surfaces 100s of the first semiconductor chips 100. In some example embodiments, the first insulating pattern 410 may have a triangular cross-section with the top surface of the carrier substrate 1000 and the side surface of a first semiconductor chip 100 forming the two sides, and an inclined surface connecting the top surface of the first semiconductor chip 100 to the top surface of the carrier substrate 1000 forming the third side.

Referring to FIG. 12, a first seed layer 314 may be formed on the carrier substrate 1000. The first seed layer 314 on the carrier substrate 1000 may conformally cover the top surface of the carrier substrate 1000, the inclined surfaces of the first insulating patterns 410, and the top surfaces of the first semiconductor chips 100.

According to some example embodiments of the inventive concepts, the first semiconductor chips 100 and the carrier substrate 1000 may form a stepped structure considering the shape of the first semiconductor chips 100. Since the first insulating patterns 410 with the inclined surface are formed on the side surfaces 100s of the first semiconductor chips 100, it may be possible to form the first seed layer 314 on the carrier substrate 1000 and the first semiconductor chips 100 with relative ease. Due to the presence of the first seed layer 314, an empty space or void may not be formed between the first seed layer 314 and the side surfaces 100s of the first semiconductor chips 100 or between the first seed layer 314 and the top surface of the carrier substrate 1000 when depositing the first seed layer 314. Thus, a failure rate in a process of fabricating a semiconductor package may be reduced or minimized.

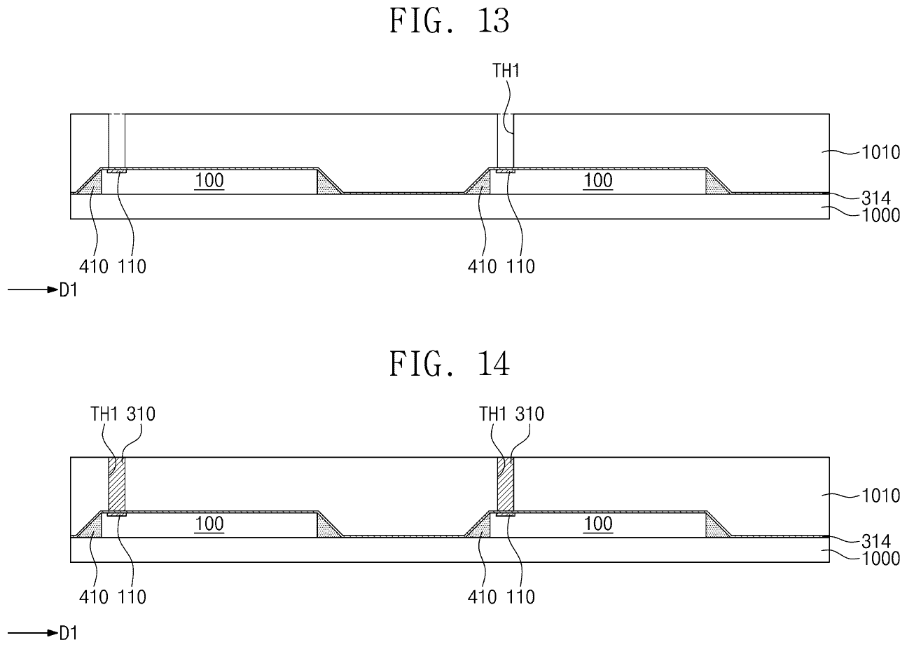

Referring to FIG. 13, a first sacrificial layer 1010 may be formed on the carrier substrate 1000. The first sacrificial layer 1010 may cover the first semiconductor chips 100, the first insulating patterns 410, and the first seed layer 314, on the carrier substrate 1000.

The first sacrificial layer 1010 may be patterned to form first penetration holes TH1 exposing the first seed layer 314. The first penetration holes TH1 may be in the location of a respective the first chip pads 110. The first penetration hole TH1 may be a through hole that exposes a top surface of the first seed layer 314.

Referring to FIG. 14, the first conductive posts 310 may be formed on the first semiconductor chips 100. For example, the formation of the first conductive posts 310 may include performing a plating process, in which the first seed layer 314 exposed by the first penetration holes TH1 is used as a seed, to fill the first penetration holes TH1 with a conductive material.

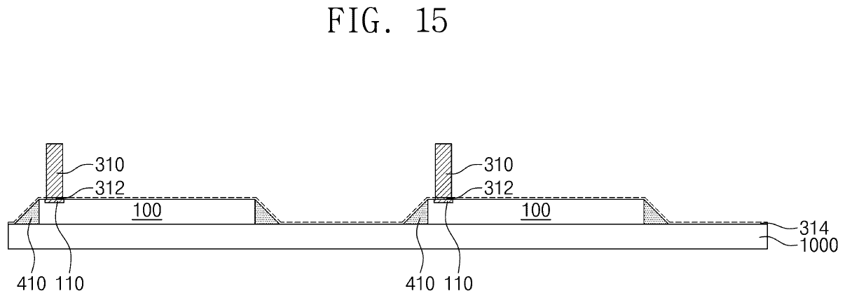

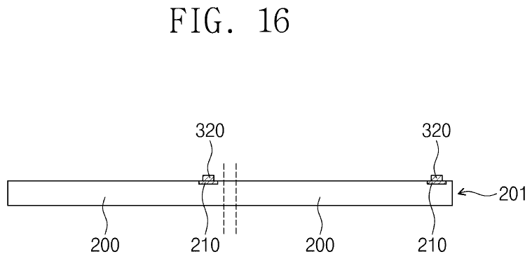

Referring to FIG. 15, the first sacrificial layer 1010 may be removed. As a result of the removal of the first sacrificial layer 1010, the first seed layer 314 may be exposed.

The first seed layer 314 may be patterned or etched using the first conductive posts 310 as a mask. As a result of the patterning process, the first seed patterns 312, which are remaining portions of the first seed layer 314 after the patterning or etching, may be formed below the first conductive posts 310. The first conductive posts 310 may be coupled to the first chip pads 110 through the first seed patterns 312.

According to some example embodiments of the inventive concepts, the first conductive posts 310 for the electric connection of the first semiconductor chip 100 may be formed through a plating process using the first sacrificial layer 1010. Thus, all the first conductive posts 310 may be formed in together in a single operation, and, as a result, the fabrication process of the semiconductor package may be simplified.

Referring to FIG. 16, the second semiconductor chips 200 may be formed on a semiconductor wafer 201. For example, an integrated circuit (e.g., transistors) may be formed on a surface of the semiconductor wafer 201, and interconnection patterns and the second chip pads 210, which are connected to the integrated circuit, may be formed.

The second conductive posts 320 may be formed on the second chip pads 210. For example, the formation of the second conductive posts 320 may include forming a mask layer on the semiconductor wafer 201 to expose the second chip pads 210 and forming a conductive material to fill or occupy regions on the second chip pads 210.

Next, the semiconductor wafer 201 may be cut along a sawing line (illustrated as dashed line) of the semiconductor wafer 201 to form the second semiconductor chips 200, which are separated from each other.

According to some example embodiments of the inventive concepts, the second conductive posts 320, which are used for the electric connection of the second semiconductor chips 200 placed at an upper level on the carrier substrate 1000, may be formed in the operation of forming the second semiconductor chips 200 on the semiconductor wafer 201. Thus, it may be possible to omit an operation of forming terminals for the electric connection on the second semiconductor chips 200 stacked, thereby reducing or minimizing the difficulty in the fabrication process of the semiconductor package.

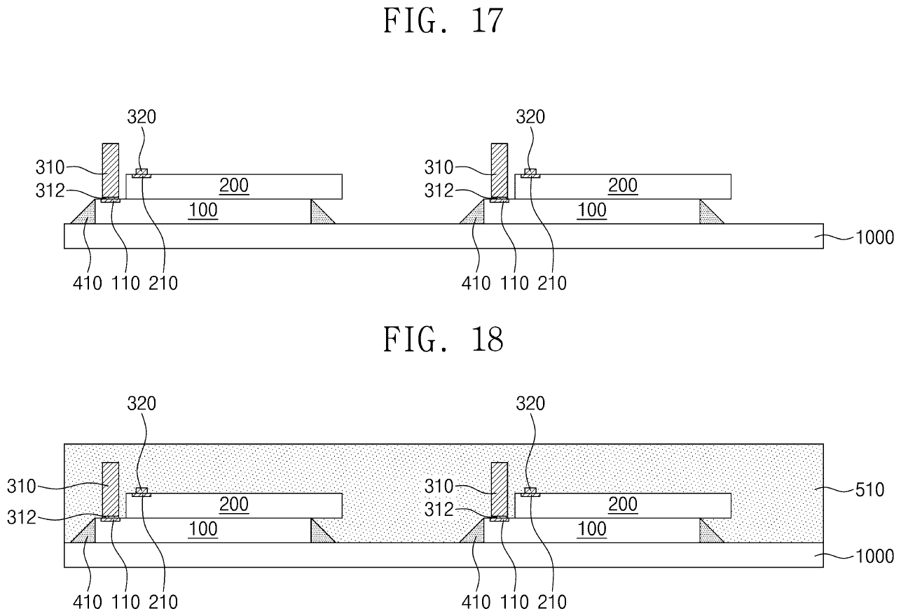

Referring to FIG. 17, the second semiconductor chips 200 may be stacked on the first semiconductor chips 100. Each of the second semiconductor chips 200 may be attached to a corresponding one of the first semiconductor chips 100 using an adhesive layer. The second semiconductor chips 200 may be disposed in a face-up manner. In other words, the rear surface of the second semiconductor chip 200 may face the carrier substrate 1000, and the second chip pads 210 of the second semiconductor chips 200 and the second conductive posts 320 may be disposed to be opposite to the carrier substrate 1000. The first and second semiconductor chips 100 and 200 may be shifted or offset from each other in the direction of the first direction D1 to expose the first chip pads 110.

Referring to FIG. 18, the first mold layer 510 may be formed on the carrier substrate 1000. For example, the formation of the first mold layer 510 may include coating a molding material on the top surface of the carrier substrate 1000 to bury the first and second semiconductor chips 100 and 200 and the first and second conductive posts 310 and 320 and curing the molding material. In some example embodiments, the molding material may include an epoxy molding compound.

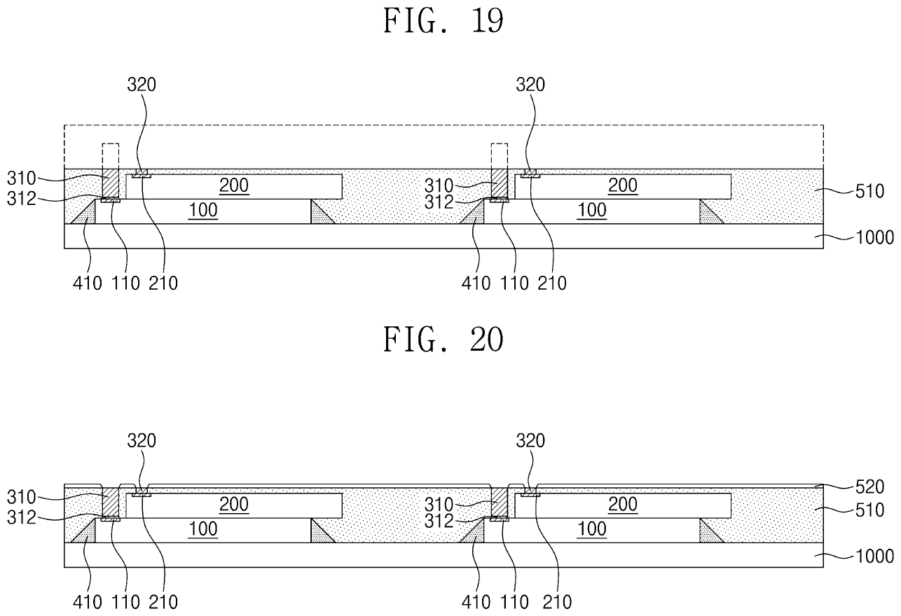

Referring to FIG. 19, a thinning process may be performed on the first mold layer 510. The thinning process may include a chemical mechanical polishing (CMP) process or a grinding process. The upper portions of the first mold layer 510 may be removed using the thinning process. The thinning process may expose the top surfaces of the first and second conductive posts 310 and 320. During the thinning process, upper portions of the first and second conductive posts 310 and 320 may be removed.

Referring to FIG. 20, the passivation layer 520 may be formed on the first mold layer 510. Initially, an insulating layer may be formed on the first mold layer 510. The insulating layer may include an insulating polymer or a photoimageable polymer. Thereafter, the insulating layer may be patterned to form the passivation layer 520, in which openings exposing the top surfaces of the first and second conductive posts 310 and 320 are formed.

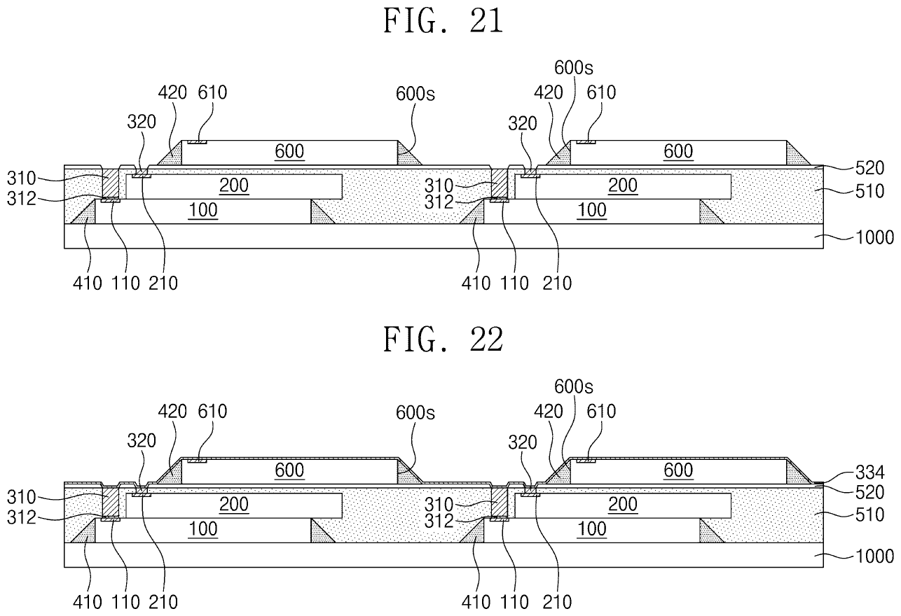

Referring to FIG. 21, the third semiconductor chips 600 may be attached to the passivation layer 520 using the adhesive member. The third semiconductor chips 600 may be provided in a face-up manner. In other words, the rear surface (also referred to as the inactive surface) of the third semiconductor chips 600 may face the passivation layer 520, and the third chip pads 610 of the third semiconductor chips 600 may be opposite to the passivation layer 520. The third semiconductor chips 600 may be disposed to be spaced apart from the openings of the passivation layer 520.

The second insulating patterns 420 may be formed on the passivation layer 520. For example, the second insulating patterns 420 may be formed by depositing an insulating material in a space between the top surface of the passivation layer 520 and the side surfaces 600s of the third semiconductor chips 600. The second insulating patterns 420 may be formed on the side surfaces 600s of the third semiconductor chips 600. The second insulating patterns 420 may cover the side surfaces 600s of the third semiconductor chips 600. The second insulating patterns 420 may surround the third semiconductor chips 600, when viewed in a plan view. The second insulating patterns 420 may fill or occupy a region on the top surface of the passivation layer 520 and between the side surfaces of the third semiconductor chips 600. In some example embodiments, the second insulating pattern 420 may have a triangular cross-section having one side in contact with the top surface of the passivation layer 520 and a second side in contact with the side surface 600s of the third semiconductor chip 600. The third side of the second insulating pattern 420 may have an inclined surface connecting the top surface of the third semiconductor chip 600 to the top surface of the passivation layer 520.

Referring to FIG. 22, a second seed layer 334 may be formed on the passivation layer 520. The second seed layer 334 on the passivation layer 520 may conformally cover the top surface of the passivation layer 520, the inclined surfaces of the second insulating patterns 420, and the top surfaces of the third semiconductor chips 600.

According to some example embodiments of the inventive concepts, the third semiconductor chips 600 and the passivation layer 520 may form a stepwise structure due to the shape of the third semiconductor chips 600. However, since the second insulating pattern 420 having the inclined surface is formed on the side surface of the third semiconductor chip 600, it may be possible to form the second seed layer 334 on the passivation layer 520 and the third semiconductor chips 600 with relative ease. When forming the second seed layer 334, an empty space or void may not be formed between the second seed layer 334 and the side surfaces 600s of the third semiconductor chips 600 or between the second seed layer 334 and the top surface of the passivation layer 520. Thus, it may be possible to reduce a failure rate when fabricating a semiconductor package.

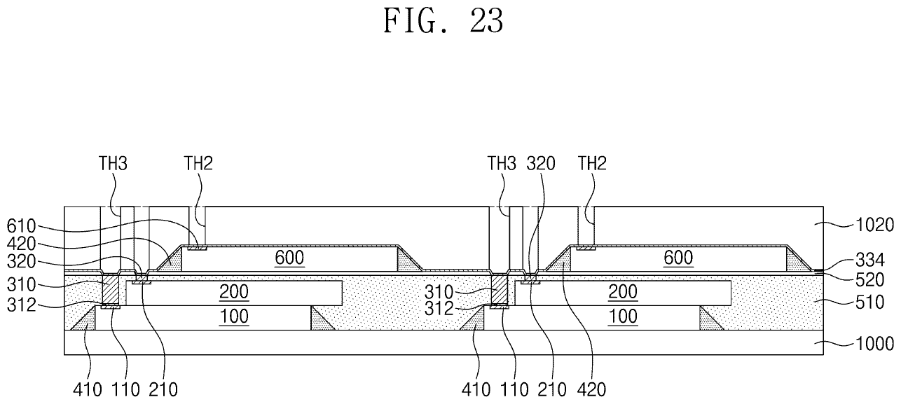

Referring to FIG. 23, a second sacrificial layer 1020 may be formed on the passivation layer 520. The second sacrificial layer 1020 on the passivation layer 520 may cover the third semiconductor chips 600, the second insulating patterns 420, and the second seed layer 334.

The second sacrificial layer 1020 may be patterned to form second penetration holes TH2 and third penetration holes TH3 exposing the second seed layer 334. The second penetration holes TH2 may be formed on respective one of the third chip pads 610. The third penetration holes TH3 may be formed on the respective one of first and second conductive posts 310 and 320. The second and third penetration holes TH2 and TH3 may expose the top surface of the second seed layer 334.

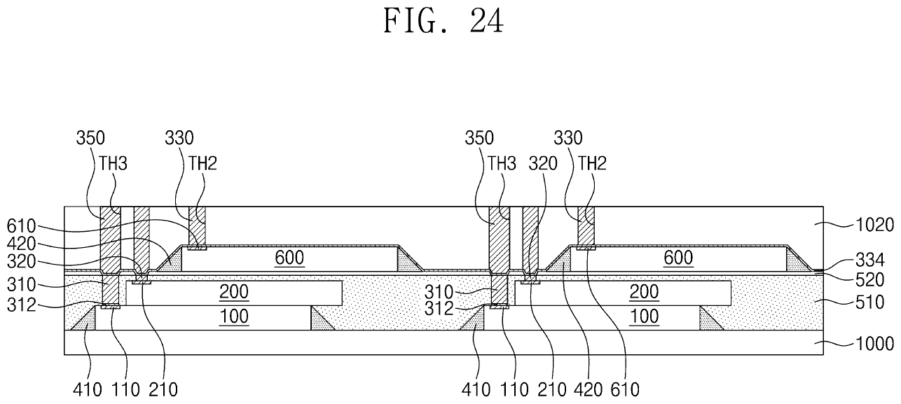

Referring to FIG. 24, the third conductive posts 330 may be formed on the third semiconductor chips 600. The fifth conductive posts 350 may be formed on the first and second conductive posts 310 and 320. For example, a plating process, in which the second seed layer 334 exposed through the second and third penetration holes TH2 and TH3 is used as a seed, may be performed to form the third conductive posts 330 filling the second penetration holes TH2 and the fifth conductive posts 350 filling the third penetration holes TH3.

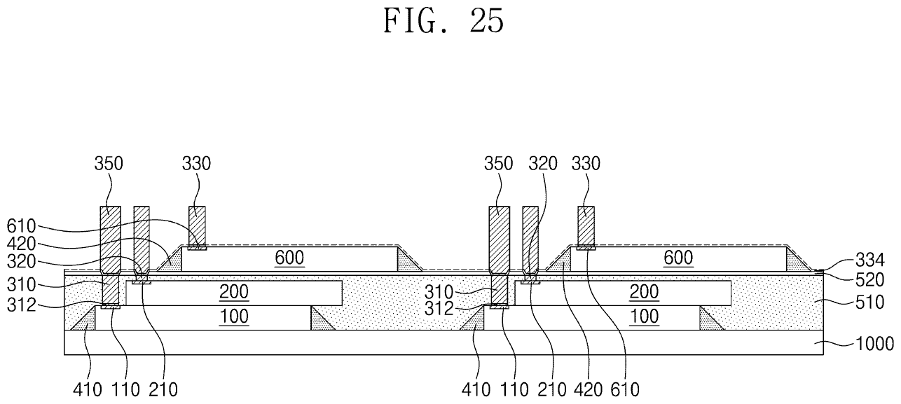

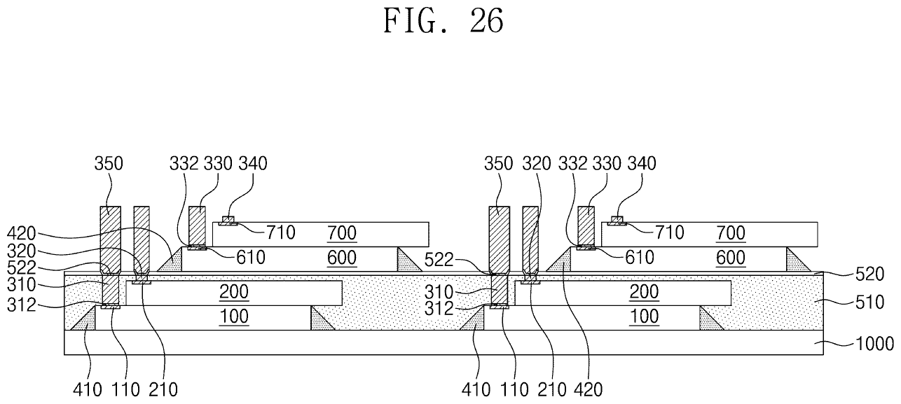

Referring to FIG. 25, the second sacrificial layer 1020 may be removed or etched. For example, the removal of the second sacrificial layer 1020 may expose the second seed layer 334.

The second seed layer 334 may be patterned or etched using the third and fifth conductive posts 330 and 350 as a mask. As a result of the patterning or etching process, the third seed patterns 332, which are remaining portions of the second seed layer 334, may be formed below the third conductive post 330. The third conductive post 330 may be coupled to the first chip pads 110 through the third seed patterns 332.

According to some example embodiments of the inventive concepts, the third conductive posts 330 for the electric connection of the third semiconductor chip 600 and the fifth conductive posts 350 for the electric connection of the first and second semiconductor chips 100 and 200 may be formed through a plating process using the second sacrificial layer 1020. That is, the third and fifth conductive posts 330 and 350 may be formed at once through a single process, and this may make it possible to simplify the fabrication process of the semiconductor package.

Referring to FIG. 26, the fourth semiconductor chips 700 may be formed. The fourth semiconductor chips 700 may be fabricated using the same or similar process as the process of fabricating the second semiconductor chips 200 described with reference to FIG. 16. For example, an integrated circuit (e.g., transistors) may be formed on a surface of a semiconductor wafer, and interconnection lines and the fourth chip pads 710, which are connected to the integrated circuit, may be formed. The fourth conductive posts 340 may be formed on the fourth chip pads 710. Next, the semiconductor wafer may be cut along a sawing line of the semiconductor wafer to form the fourth semiconductor chips 700, which are separated from each other.

The fourth semiconductor chips 700 may be stacked on the third semiconductor chips 600. Each of the fourth semiconductor chips 700 may be attached to a corresponding one of the third semiconductor chips 600 using an adhesive layer. The fourth semiconductor chips 700 may be disposed in a face-up manner. For example, the rear surface of the fourth semiconductor chip 700 may face the passivation layer 520, and the fourth chip pads 710 of the fourth semiconductor chips 700 and the fourth conductive posts 340 may be disposed to be opposite to the passivation layer 520. The third and fourth semiconductor chips 600 and 700 may be shifted or offset from each other in the first direction D1 to expose the third chip pads 610.

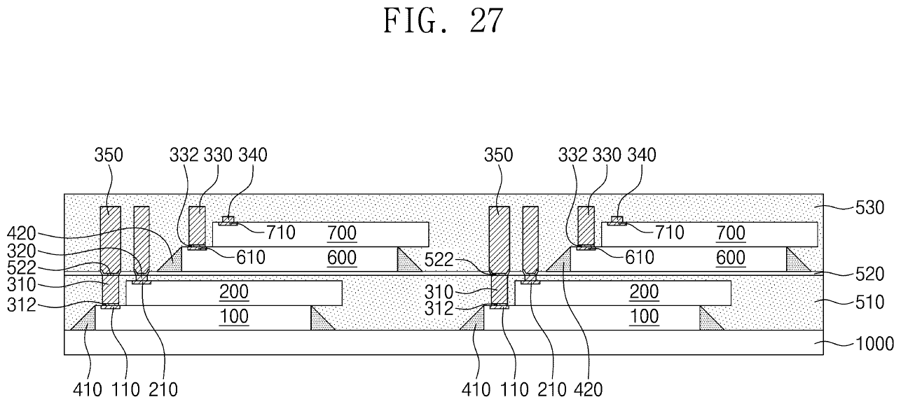

Referring to FIG. 27, the second mold layer 530 may be formed on the passivation layer 520. The formation of the second mold layer 530 may include coating the top surface of the passivation layer 520 with a molding material to bury the third and fourth semiconductor chips 600 and 700 and third to fifth conductive posts 330, 340, and 350 and curing the molding material. The molding material may include an epoxy molding compound.

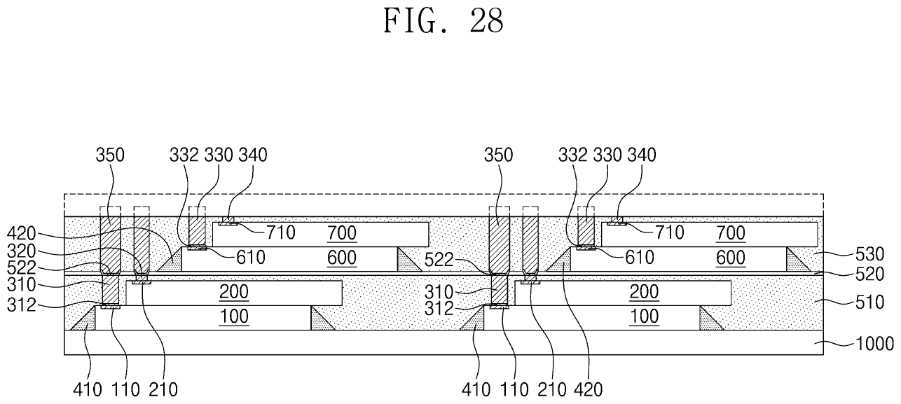

Referring to FIG. 28, a thinning process may be performed on the second mold layer 530. The thinning process may include a chemical mechanical polishing (CMP) process or a grinding process. The upper surface of the second mold layer 530 may be removed by the thinning process. The thinning process may be performed to expose top surfaces of the third to fifth conductive posts 330, 340, and 350. In some example embodiments, upper portions of the third to fifth conductive posts 330, 340, and 350 may be partially removed during the thinning process.

The pad layer 540 (FIG. 1) may be then formed on the second mold layer 530. In forming the pad layer 540, an insulating layer may initially be formed on the second mold layer 530. Next, the insulating layer may be patterned to form the pad insulating layer 542, in which openings exposing the top surfaces of the third to fifth conductive posts 330, 340, and 350 are formed. Next, the pads 544 may be formed by filling the openings with a conductive material. In some example embodiments, the package substrate 550 (FIG. 5) may be formed on the second mold layer 530 instead of the pad layer 540.

The carrier substrate 1000 may be removed. A sawing process may be performed on the pad layer 540 and the second mold layer 530 to obtains the semiconductor package of a desired size.

In a semiconductor package according to some example embodiments of the inventive concepts, conductive posts with a relatively larger width may be provided for vertical connection of semiconductor chips of a first chip stack at a lower level. Thus, the conductive posts provided between the semiconductor chips and a pad layer may robustly or resiliently support the semiconductor chips and the pad layer. In addition, the conductive posts between the semiconductor chips and the pad layer may have a low electric resistance. As a result, the semiconductor package may be provided to have improved structural stability and electric characteristics.

Since an insulating pattern having an inclined surface is formed on a side surface of a lower semiconductor chip, it may be possible to form a seed layer on a carrier substrate and the lower semiconductor chip with relative ease. Thus, it may be possible to reduce a failure rate in a process of fabricating a semiconductor package. In addition, all the conductive posts for the electric connection of the lower semiconductor chip may be formed together in a single operation, and this may simplify the fabrication process of the semiconductor package. Furthermore, conductive posts for the electric connection of an upper semiconductor chip may be formed in an operation of forming the upper semiconductor chips on a semiconductor wafer. Thus, it may be possible to omit an operation of forming a terminal for the electric connection on the upper semiconductor chip, thereby reducing or minimizing the difficulty in the fabrication process of the semiconductor package.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

1. A semiconductor package, comprising:
a first structure, wherein the first structure comprises:
a first semiconductor chip;
a second semiconductor chip on the first semiconductor chip and horizontally offset from the first semiconductor chip in a first direction;
a first insulating pattern covering side surfaces of the first semiconductor chip, a width of the first insulating pattern decreasing in a direction from a lower surface of the first semiconductor chip toward an upper surface of the first semiconductor chip;
a first mold layer surrounding the first semiconductor chip, the second semiconductor chip, and the first insulating pattern;
a first conductive post vertically penetrating the first mold layer and coupled to the upper surface of the first semiconductor chip; and
a second conductive post coupled to an upper surface of the second semiconductor chip and exposed through an upper surface of the first mold layer.

2. The semiconductor package of claim 1, wherein the first semiconductor chip comprises a first chip pad on the upper surface of the first semiconductor chip and spaced apart from the second semiconductor chip in an opposite direction of the first direction, and the first structure further comprises a first seed pattern interposed between the first conductive post and the first chip pad.

3.-4. (canceled)

5. The semiconductor package of claim 1, further comprising a second structure disposed on the first structure, wherein the second structure comprises:
a third semiconductor chip;
a fourth semiconductor chip on the third semiconductor chip and horizontally offset from the first semiconductor chip in the first direction;
a second insulating pattern covering side surfaces of the third semiconductor chip, a width of the second insulating pattern decreasing in a direction from a lower surface of the third semiconductor chip toward an upper surface of the third semiconductor chip;
a second mold layer enclosing the third semiconductor chip, the fourth semiconductor chip, and the second insulating pattern;
a third conductive post vertically penetrating the second mold layer and coupled to the upper surface of the third semiconductor chip;
a fourth conductive post coupled to an upper surface of the fourth semiconductor chip and exposed through an upper surface of the second mold layer; and
fifth conductive posts vertically penetrating the second mold layer and electrically connected to the first and second conductive posts of the first structure.

6. The semiconductor package of claim 5, further comprising a passivation layer between the first structure and the second structure,
wherein the passivation layer covers the upper surface of the first mold layer of the first structure, and
the passivation layer covers a lower surface of the second mold layer of the second structure, the lower surface of the third semiconductor chip, and a lower surface of the second insulating pattern.

7. (canceled)

8. The semiconductor package of claim 5, further comprising outer pads on the second structure,
wherein the outer pads are on the upper surface of the second mold layer of the second structure, and
the outer pads are connected to the third to fifth conductive posts of the second structure.

9. The semiconductor package of claim 5, further comprising a redistribution substrate disposed on the second structure,
wherein the redistribution substrate comprises a substrate insulating layer covering the second mold layer of the second structure and a substrate interconnection pattern in the substrate insulating layer, and
the substrate interconnection pattern penetrates the substrate insulating layer and is coupled to an upper surface of at least one of the third to fifth conductive posts of the second structure.

10. (canceled)

11. The semiconductor package of claim 1, wherein the first insulating pattern covers an entirety of the side surfaces of the first semiconductor chip, and
an uppermost portion of the first insulating pattern is located at a same vertical level as an uppermost surface of the first semiconductor chip.

12. The semiconductor package of claim 1, wherein an uppermost portion of the first insulating pattern contacts the upper surface of the first semiconductor chip, and
the first insulating pattern has an inclined surface connected to the upper surface of the first semiconductor chip.

13. (canceled)

14. The semiconductor package of claim 1, wherein the first mold layer contacts side surfaces of the second semiconductor chip.

15. The semiconductor package of claim 1, wherein a lower surface of the first mold layer, the lower surface of the first semiconductor chip, and a lower surface of the first insulating pattern are coplanar.

16.-17. (canceled)

18. A semiconductor package, comprising:
a first chip stack including a stack of first semiconductor chips, each of the first semiconductor chips having a first chip pad on an upper surface thereof;
a first mold layer covering the first chip stack;
a passivation layer covering an upper surface of the first mold layer;
first conductive posts vertically penetrating the first mold layer and coupled to the first chip pads; and
first seed patterns vertically penetrating the passivation layer and connected to the first conductive posts.

19. The semiconductor package of claim 18, further comprising a first insulating pattern covering side surfaces of a lowermost one of the first semiconductor chips of the first chip stack.

20. (canceled)

21. The semiconductor package of claim 19, wherein an uppermost portion of the first insulating pattern contacts the upper surface of the lowermost one of the first semiconductor chips, and
the first insulating pattern has an inclined surface connected to the upper surface of the lowermost one of the first semiconductor chips.

22.-24. (canceled)

25. The semiconductor package of claim 18, further comprising a second seed pattern interposed between the first chip pad of a lowermost one of the first semiconductor chips of the first chip stack and one of the first conductive posts.

26.-28. (canceled)

29. The semiconductor package of claim 18, further comprising:
a second chip stack including a stack of second semiconductor chips stacked on the passivation layer, and each of which has a second chip pad on an upper surface thereof;
a second mold layer on the passivation layer to cover the second chip stack;
second conductive posts vertically penetrating the second mold layer and coupled to the second chip pads;
third conductive posts provided to vertically penetrate the second mold layer and electrically connected to the first conductive posts; and
pads provided on an upper surface of the second mold layer and connected to the second and third conductive posts,
wherein the first seed patterns connect the first conductive posts to the third conductive posts.

30.-31. (canceled)

32. A semiconductor package, comprising:
a first structure, wherein the first structure comprises:
a first semiconductor chip having a first chip pad provided on an upper surface thereof;
a second semiconductor chip disposed on the first semiconductor chip and horizontally offset from the first semiconductor chip in a first direction, the second semiconductor chip having a second chip pad on an upper surface thereof;
a first mold layer covering the first semiconductor chip and the second semiconductor chip;
a first seed pattern on an upper surface of the first chip pad;
a first conductive post vertically penetrating the first mold layer and in contact with the first seed pattern; and
a second conductive post vertically penetrating the first mold layer and in contact with the second chip pad.

33. The semiconductor package of claim 32, wherein the first structure further comprises a first insulating pattern covering side surfaces of the first semiconductor chip, and
a width of the first insulating pattern decreases in a direction from a lower surface of the first semiconductor chip toward the upper surface of the first semiconductor chip.

34. (canceled)

35. The semiconductor package of claim 33, wherein an uppermost portion of the first insulating pattern contacts the upper surface of the first semiconductor chip, and
the first insulating pattern has an inclined surface connected to the upper surface of the first semiconductor chip.

36.-39. (canceled)

40. The semiconductor package of claim 32, further comprising a second structure disposed on the first structure, wherein the second structure comprises:
a third semiconductor chip having a third chip pad on an upper surface t hereof;
a fourth semiconductor chip on the third semiconductor chip and horizontally offset from the third semiconductor chip in the first direction, the fourth semiconductor chip having a fourth chip pad on an upper surface of the fourth semiconductor chip;
a second mold layer covering the third semiconductor chip and the fourth semiconductor chip;
a second seed pattern on an upper surface of the third chip pad;
a third conductive post vertically penetrating the second mold layer and contacting the second seed pattern;
a fourth conductive post vertically penetrating the second mold layer and contacting the fourth chip pad; and
fifth conductive posts vertically penetrating the second mold layer and electrically connected to the first and second conductive posts of the first structure.

41. The semiconductor package of claim 40, further comprising a passivation layer between the first structure and the second structure,
wherein the passivation layer covers an upper surface of the first mold layer of the first structure, and
the passivation layer covers lower surfaces of the second mold layer and the third semiconductor chip of the second structure.

42.-50. (canceled)
